(19) United States
(12) Patent Application Publication
(10) Pub. No.: US 2009/0008763 A1
(43) Pub. Date: Jan. 8, 2009

(54) SEMICONDUCTOR PACKAGE

(75) Inventors: Min-Woo KIM, Seoul (KR); Seok-Chan LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/164,412

(22) Filed: Jun. 30, 2008

(30) Foreign Application Priority Data
Jul. 6, 2007 (KR) 2007-0068169

(51) Int. Cl. H01L 23/488

(52) U.S. Cl. 257/686; 257/E23.023

(57) ABSTRACT

A semiconductor package, which may include a structure of a semiconductor package having a minimized mounting area and height. The semiconductor package may include a board, a first package comprising at least one first semiconductor chip, and disposed on the board so as to be supported, a second package comprising at least one second semiconductor chip, and disposed on the board so as be supported, and a third package that comprises at least one third semiconductor chip, the third package having a cross-sectional area greater than a cross-sectional area of the first package, the third package being disposed on the first package and the second package so as to be supported, wherein the cross-sectional areas of the third package and the first package are taken along a plane parallel to the board.

### CROSS-REFERENCE TO RELATED PATENT APPLICATION

This application claims the benefit of Korean Patent Application No. 10-2007-0068169, filed on Jul. 6, 2007, in the Korean Intellectual Property Office, the disclosure of which is incorporated herein in its entirety by reference.

### BACKGROUND OF THE INVENTION

1. Field of the Invention

The present invention relates to a semiconductor package, and more particularly, to a structure of a semiconductor package having a minimized area and height for mounting the semiconductor package.

2. Description of the Related Art

Various electronic products including semiconductor packages have become increasingly multi-functional, and have gradually become more miniaturized. For example, cellular phones have been enhanced to include functions of an MP3 player and a camera, and functions of a portable Internet (e.g., a wireless LAN (WLAN), a wireless broadband (WIBRO) or a global positioning system (GPS)). The number of semiconductor packages to be mounted has increased due to such a tendency, and thus an area for mounting the semiconductor packages, which is occupied on a board, increases. In addition, the capacity of a memory increases due to the need for a large-capacity storage medium. Thus, since the capacity of a memory semiconductor chip needs to increase, the thickness and area of a memory package are increased.

FIG. 1 is a plan view illustrating configurations of a semiconductor package and electronic elements, which are mounted on a board 10. Referring to FIG. 1, a first package PK1, a second package PK2, and a third package PK3 are mounted on a board 10. Also, other various electronic elements are mounted on the board 10. As products such as cellular phones have become increasingly multi-functional, the number of electronic elements to be mounted on the board 10 has increased. However, as products such as cellular phones have become miniaturized, an area for mounting the electronic elements is no longer sufficient.

FIG. 2 is a plan view of the configuration of semiconductor packages mounted on a board 10 included in a cellular phone. Referring to FIG. 2, the semiconductor packages mounted on the board 10 have various sizes, according to their functions. For example, a first package, a second package and a third package have 10 mm×10 mm, 13 mm×10.5 mm and 18 mm×12 mm, respectively. When the first, second and third packages are mounted directly on the board 10, an area required for mounting the first, second and third packages is 452.5 mm².

However, there is a need for a method of reducing the area required for mounting a semiconductor package in order to satisfy the tendency for miniaturized products, as described above. In particular, there is a need for a method of reducing a mounting area while ensuring the reliability of a product.

### SUMMARY OF THE INVENTION

The present invention provides a structure of a semiconductor package, which can have reduced area and height (thickness) for mounting the semiconductor package when compared with the conventional art, and which can ensure the reliability of a product including the semiconductor package.

According to one aspect of the present invention, a semiconductor package may comprise a board, a first package comprising at least one first semiconductor chip, and disposed on the board so as to be supported, a second package comprising at least one second semiconductor chip, and disposed on the board so as be supported, and a third package that comprises at least one third semiconductor chip, the third package having a cross-sectional area greater than a cross-sectional area of the first package, the third package being disposed on the first package and the second package so as to be supported, wherein the cross-sectional areas of the third package and the first package are taken along a plane parallel to the board.

### BRIEF DESCRIPTION OF THE DRAWINGS

The above and other features and advantages of the present invention will become more apparent by describing in detail exemplary embodiments thereof with reference to the attached drawings in which:

FIG. 1 is a plan view illustrating configurations of a semiconductor package and electronic elements, which are mounted on a board;

FIG. 2 is a plan view of the configuration of semiconductor packages mounted on a board included in a cellular phone;

FIG. 3 is a cross-sectional view of a semiconductor package according to an embodiment of the present invention;

FIG. 4 is a plan view of a first package, according to an embodiment of the present invention;

FIG. 5 is a plan view of a second package, according to an embodiment of the present invention;

FIG. 6 is a plan view of a third package, according to an embodiment of the present invention;

FIG. 7 is a bottom view of the third package of FIG. 6; and

FIG. 8 is a cross-sectional view of a semiconductor package according to another embodiment of the presenting invention.

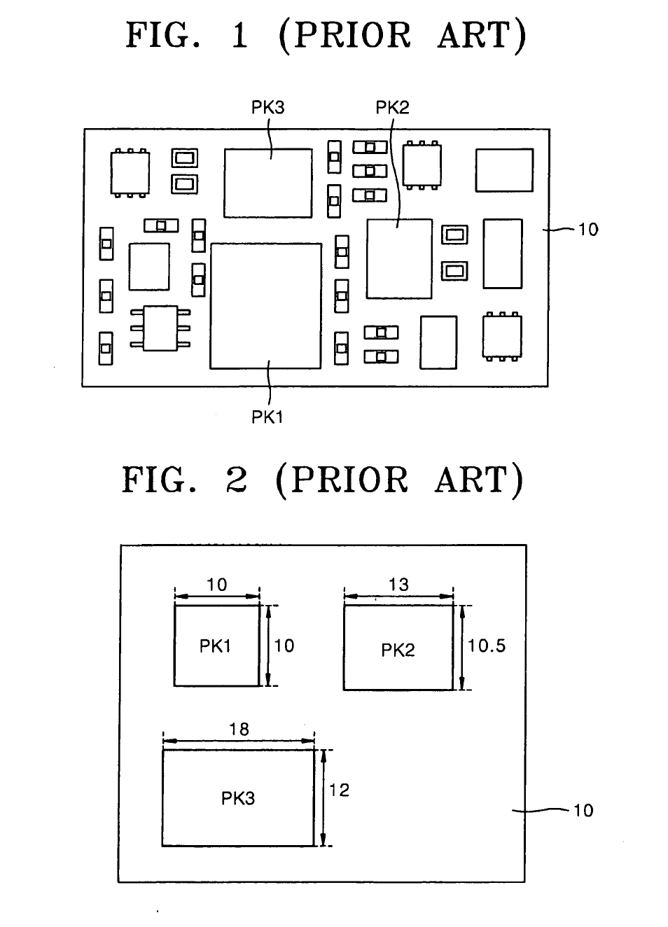

### DETAILED DESCRIPTION OF THE INVENTION

The present invention will now be described more fully with reference to the accompanying drawings, in which exemplary embodiments of the invention are shown. The invention may, however, be embodied in many different forms, and should not be construed as being limited to the embodiments set forth herein; rather, these embodiments are provided so that this disclosure will be thorough and complete, and will fully convey the concept of the invention to those of ordinary skill in the art. In the drawings, the thicknesses of layers and regions are exaggerated for clarity. Like reference numerals denote like elements throughout the specification. Throughout the specification, it will also be understood that when an element such as layer, region, or substrate is referred to as being “on” another element, it can be directly on the other element, or intervening elements may also be present.

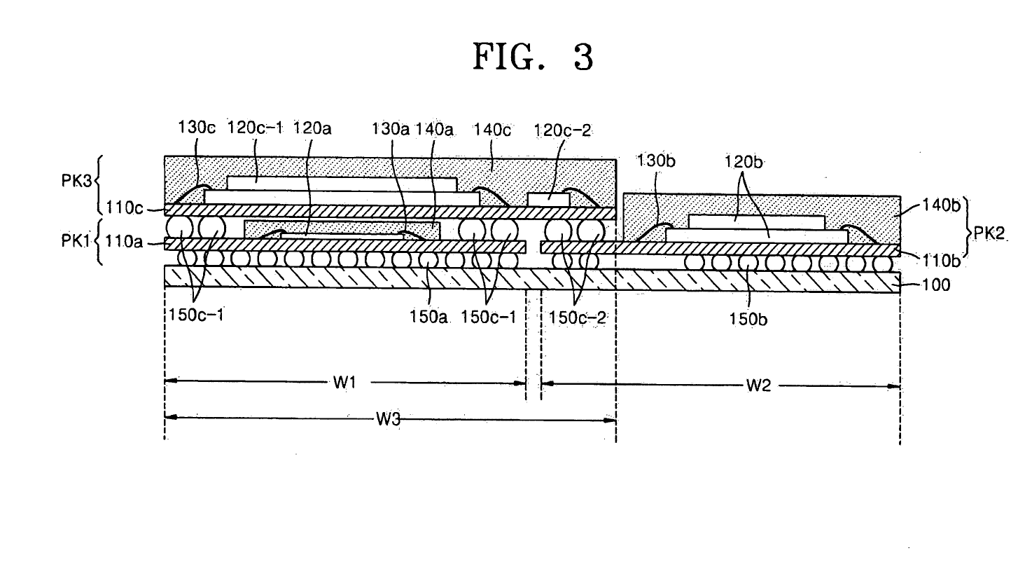

FIG. 3 is a cross-sectional view of a semiconductor package according to an embodiment of the present invention.

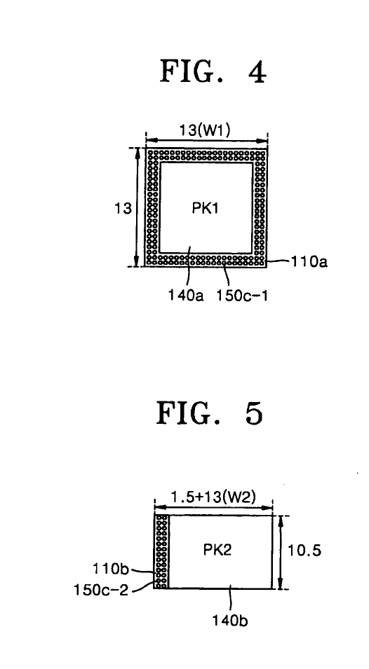

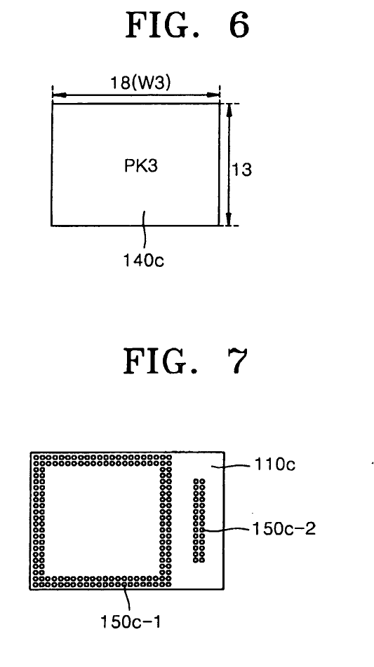

FIGS. 4 through 6 are plan views of a first package PK1, a second package PK2 and a third package PK3, respectively, according to embodiments of the present invention. FIG. 7 is a bottom view of the third package PK3 of FIG. 6.

Referring to FIGS. 3 through 7, the first package PK1 and the second package PK2 may be mounted on a board 100. The third package PK3 may be mounted on the first package PK1 and a portion of the second package PK2 so as to be supported, but is not directly on the board 100.

The board 100 may be a printed circuit board (PCB) having a single layer wiring pattern or a multi-layer wiring pattern. With regard to the first package PK1, at least one first semiconductor chip 120a may be mounted on a first substrate 110a, and a first semiconductor chip 120a may be electrically coupled to the first substrate 110a by first bonding wires 130a. A first sealing layer 140a may be formed on the first substrate 110a to surround the first semiconductor chip 120a. The first sealing layer 140a may be formed of an epoxy mold compound (EMC). The first substrate 110a may be electrically coupled to the board 100 by solder balls 150a.

With regard to the second package PK2, at least one second semiconductor chip 120b may be mounted on the second substrate 110b, and the second semiconductor chip 120b may be electrically coupled to the second substrate 110b by second bonding wires 130b. The second sealing layer 140b may be formed on the second substrate 110b to surround the second semiconductor chip 120b. The second sealing layer 140b may be formed of an EMC. The second substrate 110b may be electrically coupled to the board 100 by solder balls 150b.

With regard to the third package PK3, at least one third semiconductor chip 120c-1 and 120c-2 may be mounted on the third substrate 110c, and the third semiconductor chips 120c-1 and 120c-2 may be electrically coupled to the third substrate 110c by third bonding wires 130c. A third sealing layer 140c may be formed on the third substrate 110c to surround the third semiconductor chips 120c-1 and 120c-2. The third sealing layer 140c may be formed of an EMC.

Due to a need for a large-capacity storage medium, the size of a memory semiconductor chip continues to increase. To minimize a mounting area, various semiconductor chips may be stacked on one semiconductor package. However, stacking semiconductor chips results in an increased height (i.e., a thickness) of a storage medium. As a result, the third semiconductor chips 120c-1 and 120c-2 may be disposed laterally adjacent to each other, thereby minimizing the height (i.e., the thickness). Since the third semiconductor chips 120c-1 and 120c-2 are disposed laterally adjacent to each other, the cross-sectional area of the third substrate 110c is increased. While substantially all of the third package PK3 may be disposed directly on the first package PK1, a portion of the third package PK3 may be disposed on the first package PK1 so as to be supported. The third package PK3 may include first solder balls 150c-1 that may be disposed below the third substrate 110c and electrically coupled to the first substrate 110a of the first package PK1. The third package PK3 may be formed on the first substrate 110a, and may be supported by the first solder balls 150c-1.

As illustrated in FIG. 4, the cross-sectional area of the first sealing layer 140a may be smaller than that of the first substrate 110a. The cross-sectional areas of the first sealing layer 140a and the first substrate 110a are taken along a plane parallel to the board 100. One reason that the first sealing layer 140a may be made smaller than that of the first substrate 110a is so that the first solder balls 150c-1 may be disposed on the first substrate 110a.

The cross-sectional area of the third package PK3 may be greater than that of the first package PK1. The cross-sectional areas of the third package PK3 and the first package PK1 are taken along a plane parallel to the board 100. The plane parallel to the board 100 extends in a horizontal direction in FIG. 3. The cross-sectional area of the third substrate 110c may be greater than that of the first substrate 110a, wherein the cross-sectional areas of the third substrate 110c and the first substrate 110a are also taken along a plane parallel to the board 100. In addition, the width W3 of the third substrate 110c is greater than the width W1 of the first substrate 110a, wherein the widths W1 and W3 extend in the horizontal direction. In this case, a portion of the third substrate 110c, which corresponds substantially to difference between W3 and W1, that is, the difference between the width W3 of the third substrate 110c and the width W1 of the first substrate 110a, is not supported by the first package PK1, and is spaced apart from the board 100. Because the portion of the third substrate 110c, which is spaced apart from the board 100 may otherwise be easily damaged by mechanical or other physical impacts, the portion of the third substrate 110c, which corresponds to the difference (W3−W1), may be disposed on the second package PK2 so as to be supported. The third package PK3 may include second solder balls 150c-2 that may be disposed below the third substrate 110c and electrically coupled to the second substrate 110b of the second package PK2. The portion of the third substrate 110c, which corresponds to the difference (W3−W1), may be disposed on the second substrate 110b of the second package PK2 and supported by the second solder balls 150c-2.

As illustrated in FIG. 5, the cross-sectional area of the second sealing layer 140b may be smaller than that of the second substrate 110b. The cross-sectional areas of the second sealing layer 140b and the second substrate 110b are taken along a plane parallel to the board 100. One reason that the second sealing layer 140b may be made smaller than that of the second substrate 110b is so that the second solder balls 150c-2 may be disposed on the second substrate 110b.

Also, the second solder balls 150c-2 may function as an electrical conductor used for supplying power from the board 100 to the third substrate 110c. That is, in embodiments of the present invention, the first semiconductor chip 120a may include a central processing unit (CPU) chip, the second semiconductor chip 120b may include a storage memory chip, and the third semiconductor chips 120c-1 and 120c-2 may include a working memory. In this case, it may be necessary to dispose the first solder balls 150c-1 between the first package PK1 and the third package PK3 in order to electrically couple the first package PK1 to the third package PK3. However, since it is not necessary to electrically couple the second package PK2 to the third package PK3, the second solder balls 150c-2 may function as an electrical conductor used for supplying power from the board 100 to the third substrate 110c.

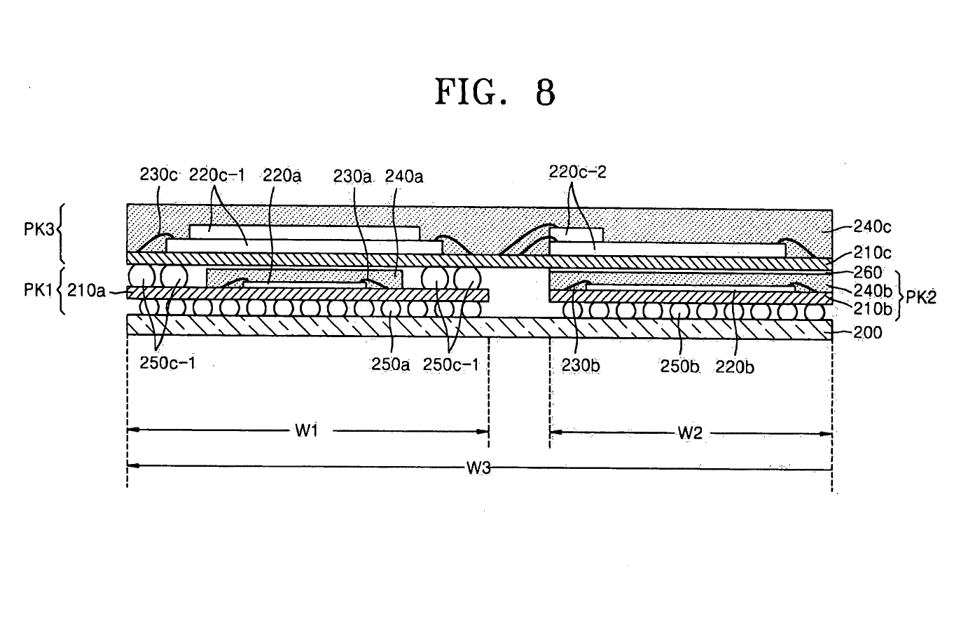

FIG. 8 is a cross-sectional view of a semiconductor package according to another embodiment of the presenting invention. Referring to FIG. 8, a portion of a third package PK3, which is disposed directly on a first package PK1, may be formed on the first package PK1 so as to be supported. The third package PK3 may include first solder balls 250c-1 that are disposed below the third substrate 210c and electrically coupled to the first substrate 210a of the first package PK1. The third package PK3 may be formed on the first substrate 210a of the of the first package PK1 and may be supported by the first solder balls 250c-1. The cross-sectional area of the third package PK3 may be greater than that of the first package PK1. The cross-sectional areas of the third package PK3 and the first package PK1 are taken along a plane parallel to a board 200. The plane parallel to the board 200 may extend in a horizontal direction. The cross-sectional area of the third substrate 210c may be greater than that of the first substrate 210a, wherein the cross-sectional areas of the third substrate 210c and the first substrate 210a are taken along the plane parallel to the board 200. That is, the width W3 of the third substrate 210c may be greater than the width W1 of the first substrate 210a, wherein the widths W1 and W3 extend in the horizontal direction. In this case, a portion of the third substrate 210c, which corresponds to W3−W1, that is, the difference between the width W3 and the width W1, is not supported by the first package PK1, and is spaced apart from the board 200. Accordingly, the portion of the third substrate 210c may be easily damaged by mechanical or other physical impacts. In an embodiment of the present invention, the portion of the third substrate 210c, which corresponds to the difference (W3−W1), may be disposed on a second sealing layer 240b substantially surrounding a second semiconductor chip 220b of the second package PK2 so as to be supported. In this case, an adhesive layer 260 may be disposed on the second sealing layer 240b such that the second package PK2 is attached to the third package PK3. The cross-sectional area of the second sealing layer 240b may be substantially the same as that of the second substrate 210b, wherein the cross-sectional areas of the second sealing layer 240b and the second substrate 210b are taken along the plane parallel to the board 200.

In some embodiments of the present invention, since only the first package PK1 and the second package PK2 are mounted directly on the board 200, a mounting area occupied on the board 100 may be about 321.25 mm2. Thus, the mounting area can be reduced by about 29% compared to that of the conventional art, which has been described in background of the invention of this specification.

Still referring to FIG. 8, the elements 230c, 220a, 230a, 240a, 250a, 230b, 250b, and 240c may generally correspond to elements 103c, 120a, 130a, 140a, 150a, 130b, 150b, and 140c, and therefore a detailed description of these is omitted. The at least one third chip 220c-1 and 220c-2 generally correspond to the at least one third chip 120c-1 and 120c-2, although the chip 220c-2 may comprise one or more chips and may be electrically coupled to the third substrate 210c using one or more bonding wires, as shown in FIG. 8.

According to some embodiments of the present invention, the first substrate (110a, 210a), the second substrate (110b, 210b) or the third substrate (110c, 210c) may be a PCB having a single layer wiring pattern or a multi-layer wiring pattern, or alternatively, may be a tape having a single layer wiring pattern or a multi-layer wiring pattern.

In addition, the first package PK1, the second package PK2 or the third package PK3 may be a land grid array type (LGA) package or a ball grid array (BGA) type package. In the above descriptions, two lower packages are mounted on the board 100, and another package is mounted on the two lower packages so as to be supported. However, according to another embodiment of the present invention, although not illustrated in FIGS. 3 through 8, a semiconductor package may include a plurality of first lower packages mounted on a board, and a second package disposed on at least two first packages selected from the plurality of first packages so as to be supported. In this case, the cross-sectional area of the second package may be greater than that of each of the first packages, wherein the cross-sectional areas of the second package and the first package are taken along a plane parallel to the board. The first packages and the second package may each be a BGA type package or a LGA type package.

According to the above embodiments, in a semiconductor package, an area for mounting a plurality of packages on a board can be reduced, and simultaneously the reliability of a product including the semiconductor package can be ensured.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A semiconductor package comprising:
a board;
a first package comprising at least one first semiconductor chip, and disposed on the board so as to be supported;
a second package comprising at least one second semiconductor chip, and disposed on the board so as be supported; and
a third package that comprises at least one third semiconductor chip, the third package having a cross-sectional area greater than a cross-sectional area of the first package, the third package being disposed on the first package and the second package so as to be supported, wherein the cross-sectional areas of the third package and the first package are taken along a plane parallel to the board.

2. The semiconductor package of claim 1, wherein the first package further comprises a first substrate on which the at least one first semiconductor chip is mounted, wherein the third package further comprises a third substrate on which the at least one third semiconductor chip is mounted, and wherein the third package further comprises first solder balls electrically coupled to the first substrate, wherein a portion of the third package is disposed on the first substrate and is supported by the first solder balls.

3. The semiconductor package of claim 2, wherein the second package further comprises a second substrate on which the at least one second semiconductor chip is mounted, wherein the third package further comprises second solder balls electrically coupled to the second substrate, wherein a portion of the third package is disposed on the second substrate and is supported by the second solder balls.

4. The semiconductor package of claim 2, wherein the second package further comprises a second sealing layer substantially surrounding the at least one second semiconductor chip, and wherein the third package is coupled to the second sealing layer.

5. The semiconductor package of claim 2, wherein a cross-sectional area of the third substrate is greater than a cross-sectional area of the first substrate, and wherein the cross-sectional areas of the third substrate and the first substrate are taken along a plane parallel to the board.

6. The semiconductor package of claim 2, wherein a width of the third substrate is greater than a width of the first substrate, and wherein the widths of the third substrate and the first substrate extend in a horizontal direction.

7. The semiconductor package of claim 1, wherein the at least one first semiconductor chip comprises a central processing unit (CPU) chip, wherein the at least one second semiconductor chip comprises a working memory chip, and wherein the at least one third semiconductor chip comprises a storage memory.

8. The semiconductor package of claim 2, wherein the at least one third semiconductor chip comprises two or more semiconductor chips, the two or more semiconductor chips being disposed laterally adjacent to each other on the third substrate.

9. The semiconductor package of claim 3, wherein at least one of the first substrate, the second substrate and the third substrate is a printed circuit board (PCB) having one of a single layer wiring pattern and a multi-layer wiring pattern.

10. The semiconductor package of claim 3, wherein at least one of the first substrate, the second substrate and the third substrate is a tape having one of a single layer wiring pattern and a multi-layer wiring pattern.

11. The semiconductor package of claim 3, wherein the second solder balls are electrical conductors used for supplying power from the board to the third substrate.

12. The semiconductor package of claim 2, wherein the first package further comprises a first sealing layer substantially surrounding the first semiconductor chip, wherein a cross-sectional area of the first sealing layer is smaller than a cross-sectional area of the first substrate in order to form the first solder balls on the first substrate, and wherein the cross-sectional areas of the first sealing layer and the first substrate are taken along a plane parallel to the board.

13. The semiconductor package of claim 3, wherein the second package further comprises a second sealing layer substantially surrounding the second semiconductor chip, wherein a cross-sectional area of the second sealing layer is smaller than a cross-sectional area of the second substrate in order to form the second solder balls on the second substrate, and wherein the cross-sectional areas of the second sealing layer and the second substrate are taken along a plane parallel to the board.

14. The semiconductor package of claim 4, further comprising an adhesive layer disposed between the second sealing layer and the third substrate.

15. The semiconductor package of claim 4, wherein a cross-sectional area of the second sealing layer is substantially the same as a cross-sectional area of the second substrate, and wherein the cross-sectional areas of the second sealing layer and the second substrate are taken along a plane parallel to the board.

16. The semiconductor package of claim 1, wherein the board is a printed circuit board (PCB) having one of a single layer wiring pattern and a multi-layer wiring pattern.

17. The semiconductor package of claim 1, wherein the first package, the second package and the third package are each a ball grid array (BGA) type package or a land grid array (LGA) type package.

18. A semiconductor package comprising:
a board;
a plurality of first packages disposed on the board so as to be supported; and
a second package disposed on at least two first packages selected from the plurality of first packages so as to be supported.

19. The semiconductor package of claim 18, wherein the plurality of first packages and the second package are each one of a BGA type package and a LGA type package.

20. The semiconductor package of claim 18, wherein a cross-sectional area of the second package is greater than a cross-sectional area of one of the first packages, and wherein the cross-sectional areas of the second package and one of the first packages are taken along a plane parallel to the board.
